(19) United States
(12) Patent Application Publication
(10) Pub. No.: US 2004/0250763 A1
(43) Pub. Date: Dec. 16, 2004

(54) Fountain cathode for large area plasma deposition

(76) Inventor: Stanford R. Ovshinsky, Bloomfield Hills, MI (US)

Correspondence Address: ENERGY CONVERSION DEVICES, INC., 2956 WATERVIEW DRIVE, ROCHESTER HILLS, MI, 48309, US

(21) Appl. No.: 10/043,010

(22) Filed: Jan. 11, 2002

(51) Int. Cl. C23C 16/00

(52) U.S. Cl. 118/715

(57) ABSTRACT

A cathode for use in a deposition chamber for the plasma enhanced deposition of semiconductor materials onto one or more webs of substrate material. The cathode is a planar fountain cathode which serves the dual functions of (1) an electrode for the plasma deposition process and (2) a fountain-like distribution conduit for the flow of fresh reaction gas to and for the evacuation of the spent reaction gas from the plasma region to maintain a uniform, constant pressure plasma reaction. The gas outlets of the inventive cathode are covered by gas dispersion plates which prevent direct, line-of-sight, flow of the process gases to the adjacent deposition substrate and more uniformly distributes the gases flowing into the plasma region between the cathode and the substrate.

### FIELD OF THE INVENTION

The present invention relates to apparatus and systems which may be utilized to mass-produce thin film semiconductor devices and more specifically to a unique fountain cathode which allows for greater uniformity of deposited semiconductor materials in plasma assisted deposition. The vertically mounted fountain cathode includes gas dispersion plates which prevent direct, line-of-sight, flow of the process gases to the adjacent deposition substrate and more uniformly distributes the gases flowing into the plasma region between the cathode and the substrate.

### BACKGROUND OF THE INVENTION

Crystalline materials which feature a regular lattice structure were formerly considered essential in the manufacture of reliable semiconductor devices. While solar cells, switches and the like having favorable characteristics continue to be so manufactured, it is recognized that preparation of crystalline materials introduces substantial costs into the semiconductor industry. Single crystal silicon and the like must be produced by expensive and time-consuming methods. Czochralski and like crystal growth techniques involve the growth of an ingot which must then be sliced into wafers and are thus inherently batch processing concepts.

Stanford R. Ovshinsky (one of the instant inventors) pioneered developments in the field of devices formed of amorphous semiconductor materials which offer a significant reduction in production costs. In particular, solar cell technology, which is dependent upon the production of a large number of devices to comprise a panel, is critically affected by processing economies. The feasibility of semiconductor devices produced by amorphous, as opposed to crystalline, materials is disclosed, for example, in U.S. Pat. No. 4,217,374 of Ovshinsky and Izu. A silicon solar cell produced by successive RF plasma glow discharge deposition of layers of various conductivities and dopings and its process of manufacture are described in U.S. Pat. No. 4,226,898 of Ovshinsky and Madan. Both of these prior art patents are hereby incorporated by reference as representative of amorphous semiconductor technology.

The feasibility of amorphous devices becomes apparent in light of the drawbacks inherent in production of crystalline devices. In addition to the aforementioned inherently “batch” nature of crystal growth, a substantial amount of the carefully grown material is lost in the sawing of the ingot into a plurality of useable wafers. Substantial surface finishing and processing effort is often required thereafter. Generally, the production of amorphous devices utilizes batch methods. As in the case of crystalline devices, such production methods impair the economic feasibility of amorphous devices such as solar cells by introducing “dead time” during which valuable equipment sits idle.

Amorphous thin film semiconductor alloys have gained acceptance for the fabrication of electronic devices such as photovoltaic cells, photoresponsive and photoconductive devices, transistors, diodes, integrated circuits, memory arrays and the like. This is because the amorphous thin film semiconductor alloys (1) can now be manufactured by relatively low cost continuous processes, (2) possess a wide range of controllable electrical, optical and structural properties and (3) can be deposited to cover relatively large areas. Among the semiconductor alloy materials exhibiting the greatest present commercial significance are amorphous silicon, germanium and silicon-germanium based alloys. Such alloys have been the subject of a continuing development effort on the part of the assignee of the instant invention, said alloys being investigated and utilized as possible candidates from which to fabricate a wide range of semiconductor, electronic and photoresponsive devices.

The assignee of the present invention is recognized as the world leader in photovoltaic technology. Photovoltaic devices produced by said assignee have set world records for photoconversion efficiency and long term stablility under operating conditions (the efficiency and stability considerations will be discussed in great detail hereinbelow). Additionally, said assignee has developed commercial processes for the continuous roll-to-roll manufacture of large area photovoltaic devices. Such continuous processing systems are disclosed in the following U.S. Patents, disclosures of which are incorporated herein by reference: U.S. Pat. No. 4,400,409, for A Method Of Making P-Doped Silicon Films And Devices Made Therefrom; U.S. Pat. No. 4,410,588, for Continuous Amorphous Solar Cell Production Systems; and U.S. Pat. No. 4,438,723, for Multiple Chamber Deposition and Isolation System And Method. As disclosed in these patents a web of substrate material may be continuously advanced through a succession of operatively interconnected, environmentally protected deposition chambers, wherein each chamber is dedicated to the deposition of a specific layer of semiconductor alloy material onto the web or onto a previously deposited layer. In making a photovoltaic device, for instance, of n-i-p type configurations, the first chamber is dedicated for the deposition of a layer of an n-type semiconductor alloy material, the second chamber is dedicated for the deposition of a layer of substantially intrinsic amorphous semiconductor alloy material, and the third chamber is dedicated for the deposition of a layer of a p-type semiconductor alloy material. The layers of semiconductor alloy material thus deposited in the vacuum envelope of the deposition apparatus may be utilized to form photoresponsive devices, such as, but not limited to, photovoltaic devices which include one or more cascaded n-i-p type cells. By making multiple passes through the succession of deposition chambers, or by providing an additional array of deposition chambers, multiple stacked cells of various configurations may be obtained. Note, that as used herein the term “n-i-p type” will refer to any sequence of n and p or n, i and p semiconductor alloy layers operatively disposed and successively deposited to form a photoactive region wherein charge carriers are generated by the absorbtion of photons from incident radiation.

The concept of utlizing multiple stacked cells, to enhance photovoltaic device efficiency, was described at least as early as 1955 by E. D. Jackson in U.S. Pat. No. 2,949,498 issued Aug. 16, 1960. The multiple cell structures therein discussed were limited to the utilization of p-n junctions formed by single crystalline semiconductor devices. Essentially the concept employed different band gap devices to more efficiently collect various portions of the solar spectrum and to increase open circuit voltage (Voc). The tandem cell device (by definition) has two or more cells with the light directed serially through each cell. In the first cell, a large band gap material absorbs only the sort wavelength light, while in subsequent cells, smaller band gap materials absorb the longer wavelengths of light which pass through the first cell. By substantially matching the generated currents from each cell, the overall open circuit voltage is the sum of the open circuit voltage of each cell, while the short circuit current thereof remains substantially constant. Such tandem cell structures can be economically fabricated in large areas by employing thin film amorphous, semiconductor alloy materials (with or without crystalline inclusions). It should be noted that Jackson employed crystalline semiconductor materials for the fabrication of his stacked cell structure; however, since it is virtually impossible to match lattice contents of differing crystalline materials, it is not possible to fabricate such crystalline tandem cell structures in a commercially feasible manner. In contrast thereto, and as the assignee of the instant invention has shown, such tandem cell structures are not only possible, but can be economically fabricated over large areas by employing the amorphous semiconductor alloy materials and the deposition techniques discussed and briefly described herein.

More particularly, the assignee of the instant invention is presently able to manufacture stacked, large area photovoltaic devices on a commercial basis by utilizing the previously referenced, continuous deposition, roll-to-roll processor. That processor is adapted to produce tandem photovoltaic cells which comprise three stacked n-i-p type photovoltaic devices disposed optically and electrically in series upon a stainless steel substrate. The processor currently includes operatively interconnected, dedicated deposition chambers, each deposition chamber adapted to sequentially deposit one of the layers of semiconductor alloy material from which the tandem device is fabricated. The deposition chambers vary in length depending upon the thickness of the particular layer of semiconductor alloy material to be deposited therein.

More specifically, the thicknesses of individual layers of semiconductor alloy material vary from approximately 100 angstroms for the doped layers to approximately 3500 angstroms for the lowermost intrinsic layer. Since the processor operates by developing an r.f. plasma which is adapted to decompose the process gases and deposits a layer of semiconductor alloy material and the thickness of the deposited layer is directly dependent upon the residence time of the web of substrate material in the deposition chamber. The processor also includes additional chambers for (1) the payoff and takeup of the web of substrate material, (2) the cleaning of the web of substrate material and (3) preventing interdiffusion of the gaseous contents of the adjacent deposition environments, said interdiffusion prevention preferably occuring in external gas gates.

The assignee of the instant invention has constructed a new and improved semiconductor processing machine for the production of high quantities of photovoltaic energy, about 25 megawatts of electrical power. It must be noted that in order to produce an annual output of 25 megawatts, the length of the machine was increased so that this 25 megawatt processor will be at least an order of magnitude longer than the previous 1.5 megawatt machine. Since not all of the reasons for this increased length are readily apparent, they will be enumerated in the following paragraphs.

A first reason for the elongation is that the new processor is configured to fabricate tandem photovoltaic devices which comprise 3 stacked cells; therefore the processor requires 9 dedicated deposition chambers. As another factor in determining the length of the processor, and as mentioned previously, the length of each of the individual deposition chambers is dependent upon the thickness of each of the layers of semiconductor alloy material to be deposited thereon. The thickness of that material is, in turn, dependent upon, the rate of deposition of particular mixtures of precursor gases and the speed of the web of substrate material passing through that chamber of the processor. Consequently, since the rate of deposition of the precursor gas mixture remains constant (Applicants find that increasing the rate of deposition of semiconductor alloy material tends to decrease the photovoltaic properties of that material), the web speed also has to be kept constant and the deposition chambers in the 25 megawatt processor are over sixteen times longer than in the previous 1.5 megawatt processor in order to deposit a sufficient quantity of semiconductor alloy material for fabricating photovoltaic devices which provides an annual output of 25 megawatts of electrical power. Even assuming that one foot wide web of substrate material were increased in size to a 2 foot width, a scaled-up version of the prior processor would still total approximately 400 feet in length. Even more significantly, in a deposition apparatus of this size, the cathode utilized for the deposition of the thickest layer of semiconductor alloy material, i.e., the bottommost intrinsic layer of semiconductor alloy material of the tandem photovoltaic device, is approximately 60 feet in length. Clearly, a 400 foot long processor which requires the incorporation of a 60 foot long cathode presents many problems. Importantly, the large areas covered by some of the deposition cathodes in the 25 megawatt processor creates problems of plasma uniformity and gas utilization within the cathode and deposition regions. Of the foregoing, plasma uniformity poses the most significant problem. Due to the large area plasma regions created by such large area cathodes, nonuniformities in the ionized precursor process gas mixtures arise. More specifically, varying compositions of the activated process gas mixture along the length of a large area cathode will give rise to irregular and nonhomogeneous plasma sub-regions, which irregularities and nonhomogeneties will result in the deposition of nonuniform, nonhomogeneous layers of semiconductor alloy material.

In the deposition of large area amorphous photovoltaic materials, uniformity of depositing species is critically important to achieving high efficiency thereof, particularly as the cathode lengths increase. In multi-junction cells this critically is magnified because, if each individual one of the layers of semiconductor alloy material is not uniformly and homogeneously deposited, the overall efficiency of the semiconductor device produced as a conglomeration of those layers suffers. It therefore becomes necessary to carefully control all processing steps which bear on the uniformity, homogeneity and general quality of the deposited semiconductor alloy material.

For example, in the laboratory small area cells can achieve efficiencies on the order of 15%. However, translating this to large area solar cells can prove to be very difficult due, in large part, to inhomogeneity of the depositing species, which in turn can be caused by uneven reactant gas distribution within the deposition plasma. This uneven distribution causes deleterious species to be formed in the plasma and thereafter to be deposited onto the substrate, causing portions of the deposited material to have different properties than those portions which do not have the deleterious species deposited thereon.

These uniformity problems have been addressed in the prior art production of amorphous silicon based photovoltaic arrays. One solution was to distribute the gas more uniformly within the plasma by using a gas distribution cathode for the deposition of such materials onto a moving web of substrate material. Such a gas distribution cathode is disclosed in U.S. Pat. No. 4,369,730 (herein incorporated by reference), which is commonly assigned to the same assignee as the instant invention. While this cathode was useful in its day, it must be improved upon to enhance the efficiencies of large area photovoltaic arrays. One way in which the prior art apparatus could be improved is to eliminate the direct, line-of-sight gas flow to the substrate from the gas distribution cathode which can force depleted species to deposit onto the substrate and to provide a more uniform dispersion of process gas into the adjacent plasma region. Thus, there is a need in the art for such an improved gas distribution cathode.

### SUMMARY OF THE INVENTION

The present invention enhances continuous deposition of photovoltaic modules by providing a vertically mounted fountain cathode for use in a plasma deposition chamber of a continuous roll-to-roll deposition system. The cathode of the invention distributes reaction gases in the plasma region bounded by the cathode and the active surface of a substrate. By providing a relatively large area (which may include a number of similar cathode modules used in conjunction with each other) and regular spacings of inlets and outlets for fresh and spent reaction gases, the device is able to deliver the gases uniformly across the entire active surface of a web-like substrate. The gas outlets of the inventive cathode are covered by gas dispersion plates which prevent direct, line-of-sight, flow of the process gases to the adjacent deposition substrate and more uniformly distributes the gases flowing into the plasma region between the cathode and the substrate, thus minimizing the effects of non-homogeneity of the depositing species.

Other advantages and features of the present invention will become apparent from the following detailed description wherein like numerals correspond to like features throughout.

### BRIEF DESCRIPTION OF THE FIGURES

FIG. 1 is a schematic depiction of a cross sectional view though the plane of the inventive cathode specifically showing the internal gas distribution manifold;

FIG. 2 is a schematic depiction of a longitudinal cross sectional view of a portion of the inventive cathode depicting the gas outlets and gas dispersion plates thereof;

FIG. 3 is a schematic depiction of a transverse cross sectional view of a portion of the inventive cathode which more clearly depicts the relationship between the gas outlets and the gas dispersion plates; and

FIG. 4 is a schematic depiction of an overview of the inventive cathode with attached mounting brackets.

### DETAILED DESCRIPTION OF THE INVENTION

The present invention relates to a cathode for a deposition chamber for plasma enhanced deposition of large areal, thin film semiconductor materials cna deposition chambers incorporating such cathodes. Specifically the cathode is a planar fountain cathode which serves the dual functions of (1) an electrode for the plasma deposition process and (2) a fountain-like distribution conduit for the flow of fresh reaction gas to and for the evacuation of the spent reaction gas from the plasma region to maintain a uniform, constant pressure plasma reaction. The cathode is electrically connected to the RF power source. The cathode is preferably vertically mounted and contains gas dispersion plates to prevents direct, line-of-sight, flow of process gases to the adjacent deposition substrate (which acts as the anode in the deposition) and more uniformly distributes the gases flowing into the plasma region between the cathode and the substrate. By providing a relatively large area (which may include a number of similar cathode modules) and regular spacings of inlets and outlets for fresh and spent reaction gases, the device is able to deliver the gases uniformly across the entire active surface of a web-like substrate.

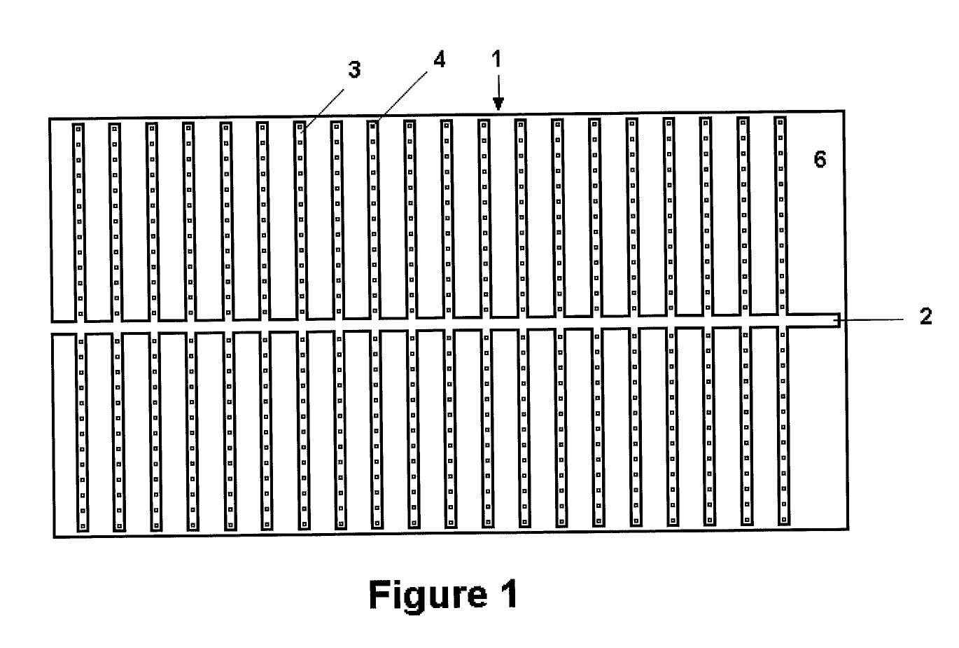

FIG. 1 shows a schematic depiction of a cross sectional view though the plane of the cathode 1. Within the cathode 1, is a main feed gas manifold 2 from which stems a plurality of finger-like secondary gas manifolds 3. A plurality of gas outlets 4 are uniformly arranged along the secondary manifolds 3. These gas outlets 4 allow gas from the manifold structure to exit the two planar surfaces of the cathode and enter plasma regions adjacent either face of the cathode 1. It is to be understood that the exit ports exist on both surfaces of the planar cathode. The gas outlets 4 allow the application of a uniform flow of fresh reaction gas to the surface of a substrate upon which semiconductor material is to be deposited and which also serves as the anode of the plasma deposition process. It should be noted that in this embodiment the gas manifolds are drilled holes within the main body of the cathode 6, but other manifold configurations are possible, such as those in U.S. Pat. No. 4,369,730, herein incorporated by reference.

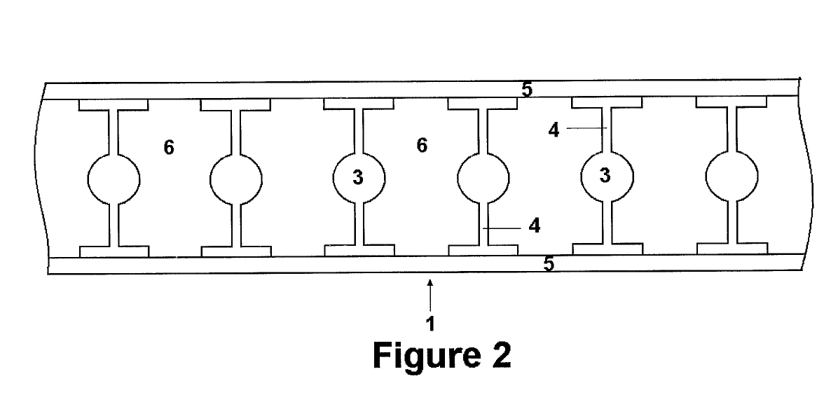

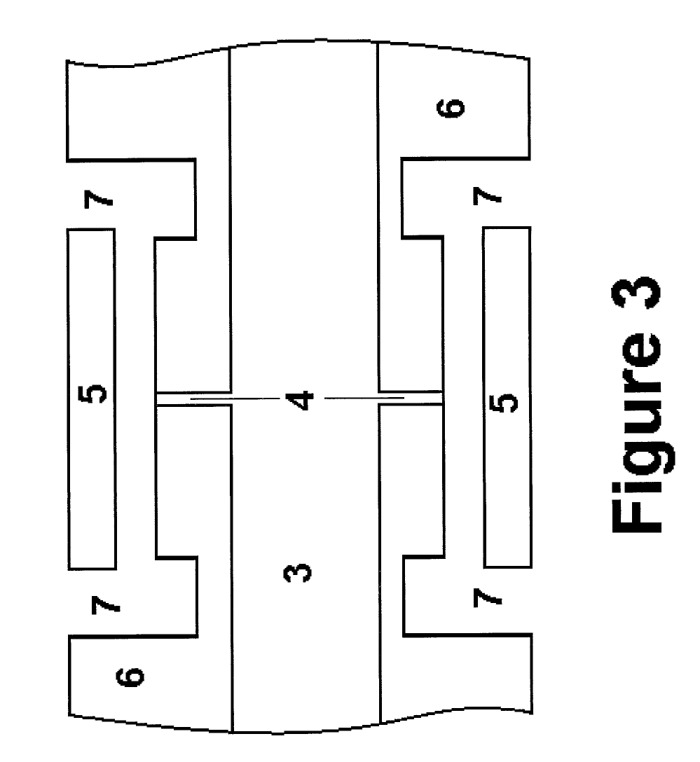

FIG. 2 shows a schematic depiction of a longitudinal cross sectional view of the cathode 1. The finger-like secondary gas manifolds 3 are seen in transverse cross section. The gas outlets 4 are covered by gas dispersion plates 5. This gas dispersion plate 5 prevents direct, line-of-sight, flow of the process gases to the adjacent deposition substrate and more uniformly distributes the gases flowing into the plasma region between the cathode and the substrate. The gas dispersion plate 5 is physically and electrically connected to the main body of the cathode 6, but there is a gap around the periphery of the gas dispersion plates 5 (more clearly visible in FIG. 3) though which the gas exits the cathode 1. The gas dispersion plates 5 may be attached to the cathode body 6 via screws or may be welded in place. The gas dispersion plates 5 may cover one or more of the gas outlets 4, but should not cover more than one longitudinal or transverse row of gas outlets 4. It should be noted that in the schematic depictions of the cathode of the instant invention the gas outlets 4 appear as simple drilled holes, however, the gas outlets 4 can also be formed by other means, such as, for example, vented screws. The gas outlets 4 are evenly spaced on the surfaces of the cathode and are preferably spaced about 1 to 4 inches apart, more preferably about 2 to 3 inches apart.

FIG. 3 shows a schematic depiction of a transverse cross sectional view of the cathode 1. The finger-like secondary gas manifolds 3 are seen in longitudinal cross section. This Figure shows more clearly how the gas outlets 4 are covered by the gas dispersion plates 5. This Figure also more clearly depicts how the gas exits the gas outlets 4, is deflected and dispersed by the gas dispersion plates 5 and exits from opening 7 between the gas dispersion plates 5 and the cathode body 6.

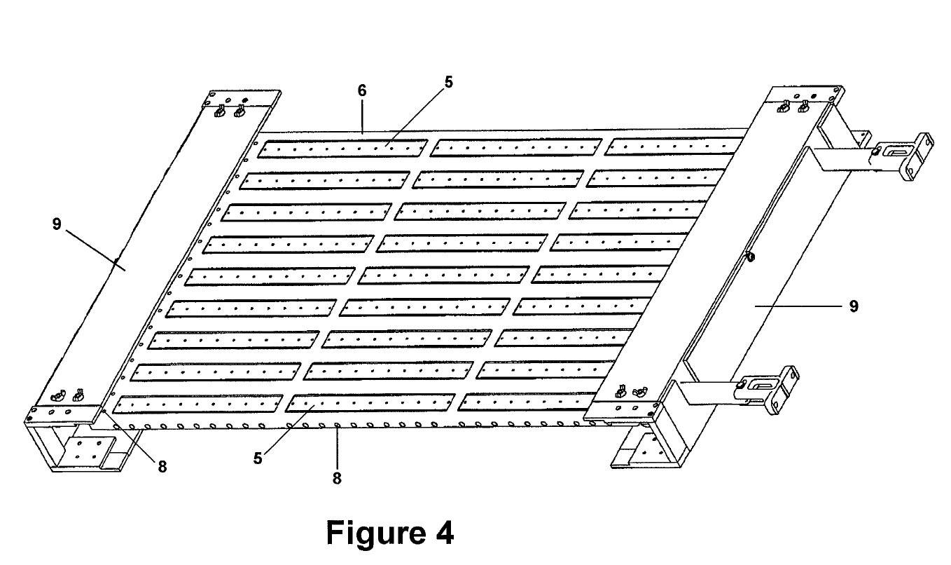

FIG. 4 is a schematic depiction of an overview of the cathode 1 of the present invention with attached mounting brackets 9. From this figure the gas dispersion plates 5 can be clearly seen attached to the main body of the cathode 6. FIG. 4 also indicates spent gas collection inlets 8. These inlets 8 are attached to a vacuum system which removes spent reactant gases from the plasma region. The inlets 8 are attached to an internal spent gas manifold system (not shown) which collects the spent gases and removes them from the deposition system via an exhaust pump (not shown). Preferably the spent gas inlets 8 are along at least one longitudinal edge of the main cathode body 6, but can be along one or more of the edges. The spent gas inlets 8 can be either along the side edge of the cathode body 6 or along the peripheral edge of the faces of the cathode body 6.

The cathode 1 of the instant invention is designed to be incorporated into a plasma deposition chamber in a vertical manner such that the planar faces of the cathode are perpendicular to the ground. The cathode is designed to create a plasma on both sides thereof and to deposit material on two webs of substrate (or two different portions of the same web) at the same time, however, the instant invention is also applicable to deposition from only a single side of the cathode if so designed or desired. The vertical placement of the cathode deters plasma polymerized species (which degrade photovoltaic devices) from depositing onto the substrate because these species fall, under the influence of gravity, downward and away from the substrate. Also, any deposition on the cathode itself, which eventually spalls and flakes off, will fall downward away from the substrates as well.

Preferably the cathode is made of a metal or metallic alloy which is nonreactive with the various process gases to be introduced into the chamber. One useful metal material is stainless steel. The cathode is preferably adapted to deposit amorphous silicon materials for the production of photovoltaic panels on webs of substrate material using various reaction gases, which may include, an inert gas such as argon or helium, a gaseous compound of silicon such as SiF₄ or silane and at least one modifier element such as fluorine or hydrogen which acts to reduce the density of localized states in the energy gap to produce a layer of material having electrical properties which closely resemble crystalline silicon.

What is claimed is:

1. A gas distribution cathode for plasma enhanced deposition of semiconductor materials onto one or more webs of substrate material comprising:
(a) a cathode body;
(b) a process gas distribution system integrated within said cathode body and including process gas outlets which are evenly dispersed on planar surfaces of said cathode body; and
(c) one or more gas dispersion plates covering said gas outlets so as to prevent direct, line-of-sight travel of precess gas from said gas outlets to a substrate upon which semiconductor material is to be deposited.

2. The gas distribution cathode of claim 1, wherein said process gas distribution system includes at least one primary process gas distribution manifold.

3. The gas distribution cathode of claim 2, wherein said process gas distribution system includes one or more secondary process gas distribution manifolds connected to said primary process gas distribution manifold.

4. The gas distribution cathode of claim 3, wherein said gas outlets are connected to said secondary process gas distribution manifolds.

5. The gas distribution cathode of claim 1, wherein said gas outlets are evenly positioned across two opposite surfaces of said cathode body.

6. The gas distribution cathode of claim 5, wherein said gas outlets are evenly positioned from 1 to 4 inches apart.

7. The gas distribution cathode of claim 6, wherein said gas outlets are evenly positioned from 2 to 3 inches apart.

8. The gas distribution cathode of claim 1, further including a spent gas evacuation system.

9. The gas distribution cathode of claim 8, wherein said spent gas evacuation system includes spent gas inlets evenly positioned along at least one peripheral edge of said cathode body.

10. The gas distribution cathode of claim 9, wherein said spent gas inlets are connected to a spent gas collection/removal manifold system.

11. The gas distribution cathode of claim 1, wherein said cathode body, said process gas outlets and said gas dispersion plates are formed from a metal or metallic alloy which is nonreactive said process gases.

12. The gas distribution cathode of claim 11, wherein said cathode body, said process gas outlets and said gas dispersion plates are formed from stainless steel.

13. A deposition chamber for the plasma enhanced deposition of semiconductor materials onto one or more webs of substrate material, said chamber including:
a gas distribution cathode comprising:
(a) a cathode body;
(b) a process gas distribution system integrated within said cathode body and including process gas outlets which are evenly dispersed on planar surfaces of said cathode body; and
(c) one or more gas dispersion plates covering said gas outlets so as to prevent direct, line-of-sight travel of precess gas from said gas outlets to a substrate upon which semiconductor material is to be deposited.

14. The deposition chamber of claim 13, wherein said process gas distribution system includes at least one primary process gas distribution manifold.

15. The deposition chamber of claim 14, wherein said process gas distribution system includes one or more secondary process gas distribution manifolds connected to said primary process gas distribution manifold.

16. The deposition chamber of claim 15, wherein said gas outlets are connected to said secondary process gas distribution manifolds.

17. The deposition chamber of claim 13, wherein said gas outlets are evenly positioned across two opposite surfaces of said cathode body.

18. The deposition chamber of claim 17, wherein said gas outlets are evenly positioned from 1 to 4 inches apart.

19. The deposition chamber of claim 18, wherein said gas outlets are evenly positioned from 2 to 3 inches apart.

20. The deposition chamber of claim 13, wherein said cathode further including a spent gas evacuation system.

21. The deposition chamber of claim 20, wherein said spent gas evacuation system includes spent gas inlets evenly positioned along at least one peripheral edge of said cathode body.

22. The deposition chamber of claim 9, wherein said spent gas inlets are connected to a spent gas collection/removal manifold system.

23. The deposition chamber of claim 13, wherein said cathode body, said process gas outlets and said gas dispersion plates are formed from a metal or metallic alloy which is nonreactive said process gases.

24. The deposition chamber of claim 23, wherein said cathode body, said process gas outlets and said gas dispersion plates are formed from stainless steel.
